(19) United States
(12) Patent Application Publication
(10) Pub. No.: US 2005/0126490 A1
(43) Pub. Date: Jun. 16, 2005

(54) Substrate temperature control apparatus

(76) Inventors: Chun-Hao Hsieh, Hsinchu (TW); Chin-Hon Fan, Hsinchu (TW); Ping-Yin Liu, Hsinchu (TW); Hung-Yin Tsai, Hsinchu (TW)

Correspondence Address: BIRCH STEWART KOLASCH & BIRCH, PO BOX 747, FALLS CHURCH, VA, 22040-0747, US

(21) Appl. No.: 10/880,546

(22) Filed: Jul. 1, 2004

(30) Foreign Application Priority Data
Dec. 12, 2003 (TW) 092135279

(51) Int. Cl. C23C 16/00

(52) U.S. Cl. 118/724

(57) ABSTRACT

A substrate temperature control apparatus adopted for use in plasma diamond coating of a substrate to reduce warping caused by excessive temperature variations includes a holding dock with a temperature sensor, a cooler and a heater installed therein. During the plasma process, if the detected temperature variation is excessive, the cooler or heater is activated to control the temperature of the upper surface and the lower surface of the substrate so that the temperature on two sides are controlled within a selected range to reduce warping.

### FIELD OF THE INVENTION

The present invention relates to a substrate temperature control apparatus adopted for use on substrates to do diamond coating by plasma and particularly to a substrate temperature control apparatus for reducing warping caused by excessive temperature variations.

### BACKGROUND OF THE INVENTION

Conventional methods for diamond coating on a thick substrate (about 5 mm) that are larger than four inches generally adopt a chemical vapor deposition (CVD) process to develop a diamond film. The plasma will increase the temperature of the substrate surface instantaneously. This will cause a large temperature difference between the surface and bottom side of the substrate, and result in uneven distribution and warping of the substrate.

To solve this problem, the earlier approach is adopting a tempering method. However, tempered by heating the plated substrate again could change the structural strength of the surface. Moreover, the common practice does not shut down the plasma when plating of the diamond film is completed. Instead, the energy of the plasma is reduced gradually to alleviate the problem of abrupt dropping of the surface temperature of the substrate. However, after plating of the diamond film is completed, to use the plasma continuously could make the surface characteristics of the substrate uncontrollable, and the desired condition could be not achievable. U.S Pat. No. 5,620,745 discloses a technique which calculates the possible stress that will occur before the substrate is used for diamond coating, then a reverse compression stress or extension stress is applied in advance to match the deformation generated by the diamond coating to reduce warping. But such a practice is too theoretical. In practice, the stress occurred to the substrate in the reaction of high temperature plasma is difficult to calculate. Moreover, a slight change of external environments (such as alterations of temperature and humidity of the atmosphere) will cause stress variations and result in unpredictable effects.

### SUMMARY OF THE INVENTION

In view of the foregoing problems, the present invention aims to provide a substrate temperature control apparatus to reduce excessive instantaneous temperature variations while the substrate is undergoing diamond coating so that the temperature of the substrate is more uniform, thereby to reducing thermal stress and warping.

The substrate temperature control apparatus according to the invention includes a holding dock, a temperature sensor, a heater and a cooler. The holding dock is used to hold a substrate. The temperature sensor is used to detect the temperature of the upper surface and the lower surface of the substrate. During the diamond coating process, when the temperature variation is too large, such as at the initial time when the plasma is activated, the temperature of the upper surface rises instantaneously. Then the heater is activated to heat the lower surface of the substrate so that temperature difference between the upper surface and the lower surface is reduced. On the other hand, when the diamond coating is completed, the temperature of the upper surface drops instantaneously. The cooler is used to lower the temperature of the lower surface so temperature difference between the upper surface and lower surface is smaller when the plasma is shut down. Thereby, the substrate temperature is more uniform and thermal stress and warping will be reduced.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of the structure of the invention.

FIG. 2 is a schematic view of the entire system for diamond coating according to the invention.

FIG. 3 is a fragmentary enlarged view according to FIG. 2.

### DESCRIPTION OF THE PREFERRED EMBODIMENTS

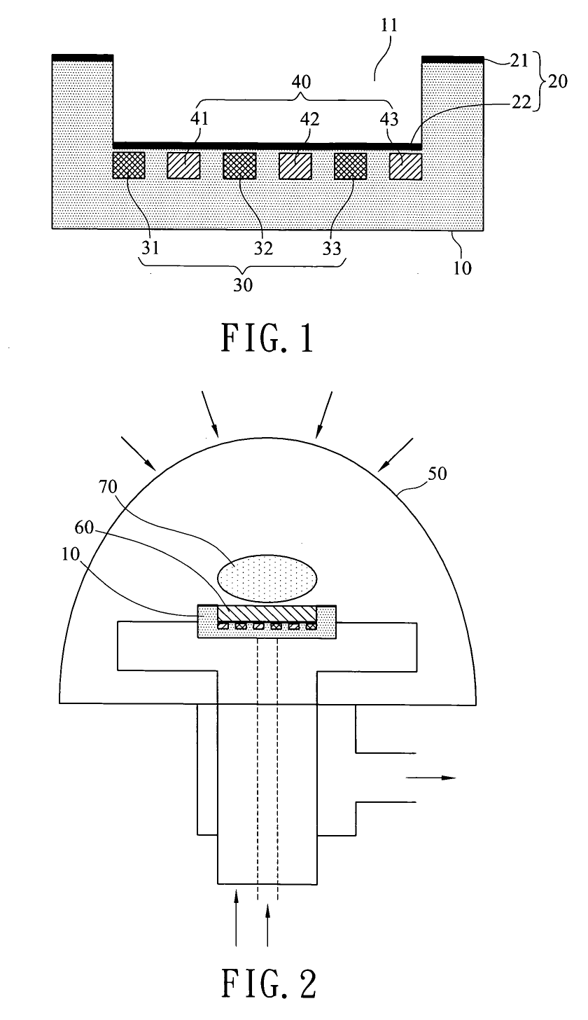

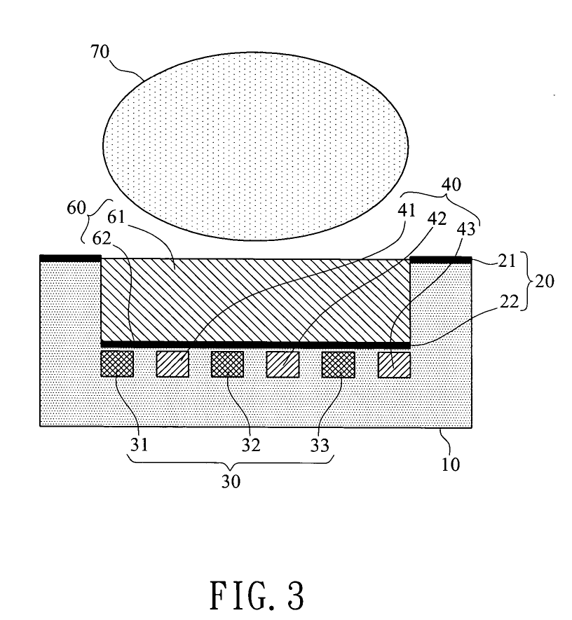

Refer to FIG. 1 for the substrate temperature control apparatus according to the invention. It includes a holding dock 10, a temperature sensor 20, a heater 30 and a cooler 40. The holding dock 10 has a holding trough 11. The temperature sensor 20 includes thermal couples 22 and 21 located respectively on the bottom of the holding trough 11 and the surface of the holding dock 10. The heater 30 and the cooler 40 are located in the holding trough 11. A substrate 60 for diamond coating, as shown in FIGS. 2 and 3, is held in a cover 50 and diamond coating is performed through plasma 70. The substrate 60 is held in the holding trough 11 of the holding dock 10. The thermal couples 21 and 22 of the temperature sensor 20 detect respectively the temperature of the upper surface 61 and the lower surface 62 of the substrate 60. The thermal couple 21 can also use infrared to perform temperature detection.

When processed by plasma 70, the temperature will rise instantaneously (working temperature is about 750° C.-850° C.), especially the temperature of the upper surface 61, which will rise significantly and result in a great temperature difference with the temperature of the lower surface 62. Hence the heater 30 is activated to heat the temperature of the lower surface 62. The heater 30 can include a plurality of electrical heaters 31, 32 and 33. And they can use chrome electric heating wires. Of course, other heating methods can also be adopted.

When the diamond coating is completed, and the plasma 70 is shut down, the thermal couples 21 and 22 detect that the temperature of the upper surface 61 drops instantaneously. The cooler 40 is used to cool the temperature of the lower surface 62 of the substrate 60. The cooler 40 can use a water-cooling approach, and include a plurality of water-cooling channel 41, 42 and 43.

On the other hand, based on the temperature difference of the upper surface 61 and lower surface 62 of the substrate 60 detected by the temperature sensor 20, a pre-determined temperature (such as 0.1° C.) may be set. When the temperature difference exceeds the pre-determined temperature, the heater 30 or cooler 40 is activated to reduce the temperature difference of the upper surface 61 and the lower surface 62 of the substrate 60. Thus the temperature of the substrate 60 is more uniform, and thermal stress and warping can be reduced.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

1. A substrate temperature control apparatus adopted for use in a plasma diamond coating process to reduce substrate warping caused by thermal stress resulting from excessive temperature variations, comprising:
a holding dock having a holding trough to hold a substrate;
a temperature sensor for detecting the temperature of an upper surface and a lower surface of the substrate held in the holding trough;
a cooler located in the holding dock to adjust the temperature of the substrate; and
a heater located in the holding dock to adjust the temperature of the substrate.

2. The substrate temperature control apparatus of claim 1, wherein the temperature sensor is located respectively on the bottom of the holding trough and a surface of the holding dock to detect the temperature of the upper surface and the lower surface of the substrate.

3. The substrate temperature control apparatus of claim 2, wherein the temperature sensor is selectively a thermal couple or an infrared sensor.

4. The substrate temperature control apparatus of claim 1, wherein the temperature sensor activates the heater or the cooler to operate to adjust the temperature difference of the upper surface and the lower surface of the substrate, when it detects the temperature difference of the upper surface and the lower surface of the substrate exceeding a preset temperature.

5. The substrate temperature control apparatus of claim 1, wherein the heater is a chrome electric heating wire.

6. The substrate temperature control apparatus of claim 1, wherein the cooler is a water- cooling system.
